(19) United States
(12) Patent Application Publication
(10) Pub. No.: US 2025/0393305 A1
(43) Pub. Date: Dec. 25, 2025

(54) MANUFACTURING METHOD FOR ARRAY SUBSTRATE, AND ARRAY SUBSTRATE

(71) Applicant: INFOVISION OPTOELECTRONICS (KUNSHAN) CO., LTD., Suzhou (CN)

(72) Inventors: Te-Chen CHUNG, Suzhou (CN); Yuan-hao CHANG, Suzhou (CN); Yuan TAO, Suzhou (CN)

(73) Assignee: INFOVISION OPTOELECTRONICS (KUNSHAN) CO., LTD., Suzhou, JS (CN)

(21) Appl. No.: 18/881,313

(22) PCT Filed: May 11, 2023
(86) PCT No.: PCT/CN2023/093722

§ 371 Date: Jan. 6, 2025

(51) Int. Cl. H10D 86/40; H10D 86/01

(52) U.S. Cl. CPC H10D 86/441; H10D 86/0231

(57) ABSTRACT

Disclosed are a manufacturing method for an array substrate, and an array substrate. The manufacturing method includes: forming a scanning line, a gate and a first insulating layer; forming a first transparent conductive layer and a negative photoresist layer, carrying out back lithography on the negative photoresist layer, and then carrying out first etching on the first transparent conductive layer; forming a semiconductor layer and a positive photoresist layer, carrying out back lithography on the positive photoresist layer, and then etching the semiconductor layer; and forming a second metal layer and a photoresist layer, using a halftone mask to carry out front lithography on the photoresist layer, first carrying out first etching on the second metal layer and carrying out second etching on the first transparent conductive layer, and after a semi-photoresist pattern layer is removed, carrying out second etching on the second metal layer.

### TECHNICAL FIELD

The present invention relates to the technical field of display technology, and in particular, to a manufacturing method for an array substrate, and an array substrate.

### DESCRIPTION OF RELATED ART

With the development of display technology, thin and lightweight display panels are very popular among consumers, especially thin and lightweight liquid crystal display panels (LCD).

An existing display device includes a thin film transistor array substrate (TFT array substrate), a color filter substrate (CF substrate) and liquid crystal molecules filled between the TFT array substrate and the CF substrate. During operation of the display device, driving voltages are respectively applied to the pixel electrode of the TFT array substrate and the common electrode of the CF substrate, or driving voltages are respectively applied to the common electrode and the pixel electrode of the TFT array substrate, to control the rotation direction of the liquid crystal molecules between the two substrates, so as to refract the backlight provided by a backlight module of the display device, thereby displaying the pictures.

### BRIEF SUMMARY OF THE INVENTION

### Technical Problem

The manufacturing process of thin film transistor array substrates in existing technology is relatively complex, for example, a first masking process is required when manufacturing the scanning line and the gate; a second masking process is required when manufacturing the active layer; a third masking process is required when manufacturing the pixel electrode; a fourth masking process is required when manufacturing the data line, the source and the drain; a fifth masking process is required when forming the contact hole in the insulating layer; and a sixth masking process is required when manufacturing the common electrode. Therefore, in the existing technology, at least six masking processes and six types of masks are needed for the manufacturing of thin film transistor array substrate, which is complex, time-consuming, and costly.

### Technical Solution

In order to overcome the shortcomings and deficiencies in the prior art, the object of the present invention is to provide a manufacturing method for an array substrate and an array substrate, so as to solve the problem that the manufacturing process for array substrates is complex in existing technology.

The object of the present invention is realized by the following technical solutions:

The present invention provides a manufacturing method for an array substrate, including:
providing a substrate;
forming a first metal layer above the substrate, and the first metal layer being etched such that the first metal layer is patterned to form a scanning line and a gate, wherein the gate is electrically connected to the scanning line;
forming a first insulating layer covering the scanning line and the gate above the substrate;
forming sequentially a first transparent conductive layer and a negative photoresist layer above the first insulating layer, and using the first metal layer as a mask, the negative photoresist layer being subjected to photolithography treatment from the side of the substrate away from the negative photoresist layer to remove the negative photoresist layer in the areas corresponding to the scanning line and the gate, the negative photoresist layer being patterned to form a negative photoresist pattern layer, and using the negative photoresist pattern layer as a shield, the first transparent conductive layer being etched for the first time to remove the first transparent conductive layer in the areas corresponding to the scanning line and the gate;
forming sequentially a semiconductor layer and a positive photoresist layer above the first insulating layer, and using the first metal layer as a mask, the positive photoresist layer being subjected to photolithography from the side of the substrate away from the positive photoresist layer, the positive photoresist layer being patterned to form a positive photoresist pattern layer, the positive photoresist pattern layer corresponding to the scanning line and the gate, and using the positive photoresist pattern layer as a shield, the semiconductor layer being etched to form an active layer corresponding to the scanning line and the gate;
forming sequentially a second metal layer and a photoresist layer above the first transparent conductive layer and the semiconductor layer, and using a half tone mask as a shield, the photoresist layer being subjected to photolithography from the side of the half tone mask away from the substrate, the photoresist layer being patterned to form a first photoresist pattern layer, the first photoresist pattern layer including a completely photolithographed non-photoresist pattern area, a partially photolithographed semi-photoresist pattern layer, and an un-photolithographed full photoresist pattern layer;
using the first photoresist pattern layer as a shield, the second metal layer being etched for the first time and the first transparent conductive layer being etched for the second time, the first transparent conductive layer being patterned to form a first electrode and a first conductive portion, wherein the first conductive portion is electrically connected to the active layer;
using a photoresist ashing process to remove the semi-photoresist pattern layer such that the first photoresist pattern layer is formed into a second photoresist pattern layer, and using the second photoresist pattern layer as a shield, the second metal layer being etched for the second time, the second metal layer forming a data line, a source, and a second conductive portion, while the first electrode and the active layer in the channel region are exposed, wherein the data line is electrically connected to the source, at least one of the first conductive portion and the second conductive portion serves as a drain, the first electrode and the channel region of the active layer correspond to the semi-photoresist pattern layer, while the data line, the source and the second conductive portion correspond to the full photoresist pattern layer.

Further, the manufacturing method further includes:
after etching the semiconductor layer, first forming a doped semiconductor layer above the first transparent conductive layer and the semiconductor layer, then forming sequentially the second metal layer and the photoresist layer above the doped semiconductor layer;
after the second metal layer is etched for the first time, the doped semiconductor layer being etched for the first time using the first photoresist pattern layer as a shield;
after the second metal layer is etched for the second time, the doped semiconductor layer being etched for the second time using the second photoresist pattern layer as a shield, the doped semiconductor layer being patterned to form a doped semiconductor pattern layer, wherein the doped semiconductor pattern layer is disconnected in the channel region.

Further, the manufacturing method further includes:
after forming the semiconductor layer, first forming a doped semiconductor layer above the semiconductor layer, then forming the positive photoresist layer above the doped semiconductor layer;
before the semiconductor layer is etched, the doped semiconductor layer being etched for the first time using the positive photoresist pattern layer as a shield;
after the second metal layer is etched for the second time, the doped semiconductor layer being etched for the second time using the second photoresist pattern layer as a shield, the doped semiconductor layer forming a doped semiconductor pattern layer, wherein the doped semiconductor pattern layer is disconnected in the channel region, and the first conductive portion and the second conductive portion are electrically connected.

Further, the first electrode is a pixel electrode, and the first electrode is electrically connected to the first conductive portion.

Further, the manufacturing method further includes:
forming a second insulating layer above the first insulating layer, the second insulating layer being etched such that the second insulating layer forms a contact hole in the areas corresponding to the first electrode and the second conductive portion;
forming a second transparent conductive layer above the second insulating layer, the second transparent conductive layer being etched such that the second transparent conductive layer is patterned to form a second electrode and a third conductive portion, wherein the second electrode is a common electrode, both the third conductive portion and the first electrode are insulated from the second electrode, and the third conductive portion electrically connects the first electrode and the second conductive portion through the contact hole.

Further, the first electrode is a common electrode, the first electrode and the first conductive portion are insulated from each other, and the manufacturing method further includes:
forming a second insulating layer above the first insulating layer, the second insulating layer being etched to form a contact hole in the area corresponding to the second conductive portion;
forming a second transparent conductive layer above the second insulating layer, the second transparent conductive layer being etched such that the second transparent conductive layer is patterned to form a second electrode and a third conductive portion, wherein the second electrode is a pixel electrode, the third conductive portion is electrically connected to the second electrode, the second electrode and the first electrode are insulated from each other, and the third conductive portion is electrically connected to the second conductive portion through the contact hole.

Further, the first transparent conductive layer is made of metal oxide semiconductor, and the manufacturing method further includes:
before forming the second metal layer, the first transparent conductive layer being first subjected to conductive treatment;
after the second metal layer is etched for the second time, the active layer exposed in the channel region being subjected to hydrogen channel treatment using a hydrogen doping process.

Further, the first transparent conductive layer is made of metal oxide semiconductor, and the manufacturing method further includes:
after the second metal layer is etched for the second time, the first transparent conductive layer being subjected to conductive treatment.

Further, the manufacturing method further includes:
the first transparent conductive layer being subjected to conductive treatment using a hydrogen doping process, and the active layer exposed in the channel region also being subjected to hydrogen channel treatment simultaneously.

The present invention also provides an array substrate manufactured by the manufacturing method as described above, and the array substrate includes:
a substrate;
a first metal layer provided above the substrate, wherein the first metal layer includes a scanning line and a gate, the gate is electrically connected to the scanning line;
a first insulating layer provided above the first metal layer, the first insulating layer covering the scanning line and the gate;
a first transparent conductive layer and a semiconductor layer provided above the first insulating layer, wherein the first transparent conductive layer includes a first electrode and a first conductive portion, the semiconductor layer includes an active layer, and the first conductive portion is electrically connected to the active layer;
a second metal layer provided above the first transparent conductive layer and the semiconductor layer, wherein the second metal layer includes a data line, a source and a second conductive portion, the data line is electrically connected to the source, and at least one of the first conductive portion and the second conductive portion serves as a drain.

Further, the array substrate further includes a doped semiconductor layer arranged between the semiconductor layer and the second metal layer, the doped semiconductor layer includes a doped semiconductor pattern layer formed by patterning, and the doped semiconductor pattern layer is disconnected in the channel region of the active layer.

Further, the first electrode is a pixel electrode, and the first electrode is electrically connected to the first conductive portion.

Further, the array substrate further includes:
a second insulating layer provided above the first insulating layer, wherein the second insulating layer is provided with a contact hole in the areas corresponding to the first electrode and the second conductive portion;
a second transparent conductive layer provided above the second insulating layer, wherein the second transparent conductive layer includes a second electrode and a third conductive portion, the second electrode is a common electrode, the third conductive portion and the first electrode are both insulated from the second electrode, and the third conductive portion electrically connects the first electrode and the second conductive portion through the contact hole.

Further, the second conductive portion and the first conductive portion are electrically connected.

Further, the first electrode is a common electrode, the first electrode and the first conductive portion are insulated from each other, and the array substrate further includes:
a second insulating layer provided above the first insulating layer, wherein the second insulating layer is provided with a contact hole in the area corresponding to the second conductive portion;
a second transparent conductive layer provided above the second insulating layer, wherein the second transparent conductive layer includes a second electrode and a third conductive portion, the second electrode is a pixel electrode, the third conductive portion is electrically connected to the second electrode, the first electrode and the second electrode are insulated from each other, and the third conductive portion is electrically connected to the second conductive portion through the contact hole.

### Beneficial Effects

By using the first metal layer as a mask and employing backside exposure, and alternating the use of negative and positive photoresists, the first transparent conductive layer is etched for the first time and the semiconductor layer is etched. Then, the first transparent conductive layer is etched for the second time and the second metal layer is etched twice by using a half-tone mask, thereby reducing the number of masks, simplifying the manufacturing process, and reducing the manufacturing costs; moreover, after etching the second metal layer twice, the first transparent conductive layer will still be retained under the data line, the source, and the second conductive portion, thereby reducing the impedance of the data line, the source, and the second conductive portion.

### BRIEF DESCRIPTION OF THE DRAWINGS

FIG. 1 is a schematic cross-sectional view of the array substrate in the first embodiment of the present invention.

FIGS. 2a to 2p are schematic diagrams of the manufacturing method for the array substrate in the first embodiment of the present invention.

FIG. 3 is a schematic cross-sectional view of the display panel in the first embodiment of the present invention.

FIG. 4 is a schematic cross-sectional view of the array substrate in the second embodiment of the present invention.

FIG. 5 is a schematic plan view of the array substrate in the second embodiment of the present invention.

FIG. 6 is a first cross-sectional schematic diagrams of the manufacturing method for the array substrate in the second embodiment of the present invention.

FIG. 7 is a second cross-sectional schematic diagram of the manufacturing method for the array substrate in the second embodiment of the present invention.

FIG. 8 is a schematic cross-sectional view of the array substrate in the third embodiment of the present invention.

FIGS. 9a to 9b are schematic cross-sectional views of the manufacturing method for the array substrate in the third embodiment of the present invention.

FIG. 10 is a schematic cross-sectional view of the array substrate in the fourth embodiment of the present invention.

FIG. 11 is a schematic plan view of the array substrate in the fourth embodiment of the present invention.

FIGS. 12a to 12c are schematic diagrams of the manufacturing method for the array substrate in the fourth embodiment of the present invention.

FIG. 13 is a schematic cross-sectional view of the display panel in the fourth embodiment of the present invention.

### DETAILED DESCRIPTION OF THE EMBODIMENTS

In order to further illustrate the technical solutions and effects of the present invention to achieve its intended purpose, the following describes the specific implementation mode, structures, features and effects of the manufacturing method for an array substrate and the array substrate provided in the present invention in combination with the drawings and the preferred embodiments as follows.

### First Embodiment

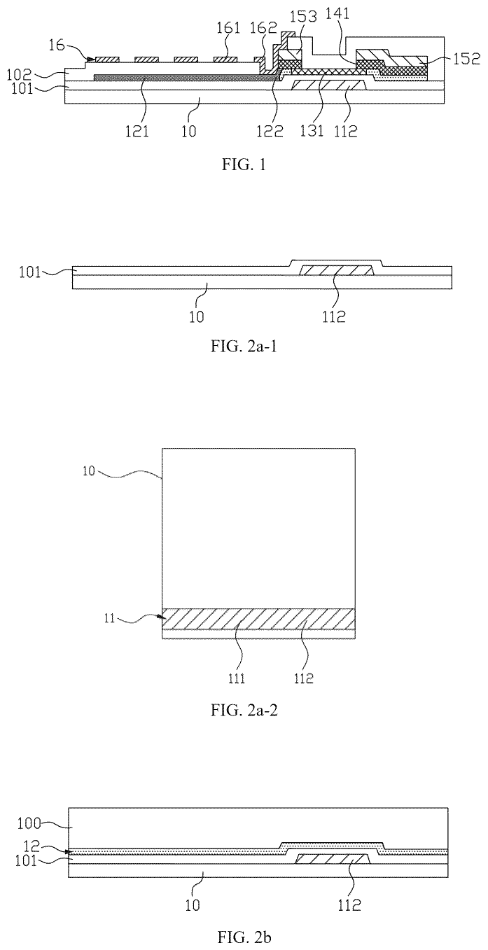

FIG. 1 is a schematic cross-sectional view of the array substrate in the first embodiment of the present invention. As shown in FIG. 1, the first embodiment of the present invention provides an array substrate, and the array substrate includes a substrate 10. The substrate 10 can be made of materials such as glass, quartz, silicon, acrylic acid, or polycarbonate, etc. The substrate 10 can also be a flexible substrate, and suitable materials for the flexible substrate include, for example, polyether sulfone (PES), polyethylene naphthalate (PEN), polyethylene (PE), polyimide (PI), polyvinyl chloride (PVC), polyethylene terephthalate (PET), or a combination thereof.

A first metal layer 11 is provided above the substrate 10. The first metal layer 11 is directly provided on the upper surface of the substrate 10. The first metal layer 11 includes a scanning line 111 and a gate 112, and the gate 112 is electrically connected to the scanning line 111. In this embodiment, a portion of the scanning line 111 serves as the gate 112, that is, the gate 112 and the scanning line 111 are located on the same straight line, thereby increasing the pixel aperture ratio. Specifically, the first metal layer 11 can be made of metals, such as copper (Cu), silver (Ag), chromium (Cr), molybdenum (Mo), aluminum (Al), titanium (Ti), manganese (Mn), nickel (Ni), etc., or a combination of the above metals, such as Al/Mo, Cu/Mo, etc. Of course, in other embodiments, the gate 112 and the scanning line 111 may not be on the same straight line, that is, the gate 112 may be provided by protruding from the scanning line 111, it is not limited herein.

A first insulating layer 101 is provided above the first metal layer 11. The first insulating layer 101 is directly provided on the upper surfaces of the substrate 10 and the first metal layer 11, and covers the scanning line 111 and the gate 112. Specifically, the first insulating layer 101 is the gate insulating layer, and the material of the first insulating layer 101 is silicon oxide (SiOx), silicon nitride (SiNx), or a combination of both.

A first transparent conductive layer 12 and a semiconductor layer 13 are provided above the first insulating layer 101. The first transparent conductive layer 12 includes a first electrode 121 and a first conductive portion 122. The semiconductor layer 13 includes an active layer 131. The first conductive portion 122 is electrically connected to the active layer 131. Specifically, the semiconductor layer 13 is made of amorphous silicon (a-Si); the first transparent conductive layer 12 can be made of metal oxide semiconductor, but a conductive treatment such as plasma treatment, ion bombardment, hydrogen (H2) doping, helium (He) doping, argon (Ar) doping, etc. is needed to be performed on the metal oxide semiconductor, such that a partial area of the first transparent conductive layer 12 is made conductive. The impedance of the first transparent conductive layer 12 after conductive treatment is lower than that before conductive treatment, and is equivalent to the impedance of indium tin oxide (ITO) or indium zinc oxide (IZO). Preferably, the metal oxide semiconductor adopts transparent metal oxide semiconductor, such as indium zinc oxide (InZnO), indium gallium oxide (InGaO), indium tin oxide (InSnO), zinc tin oxide (ZnSnO), gallium tin oxide (GaSnO), gallium zinc oxide (GaZnO), indium gallium zinc oxide (IGZO), or indium gallium zinc tin oxide (IGZTO). Of course, in other embodiments, the first transparent conductive layer 12 can also be made of transparent electrodes such as indium tin oxide (ITO) or indium zinc oxide (IZO), so that the conductive treatment is not needed.

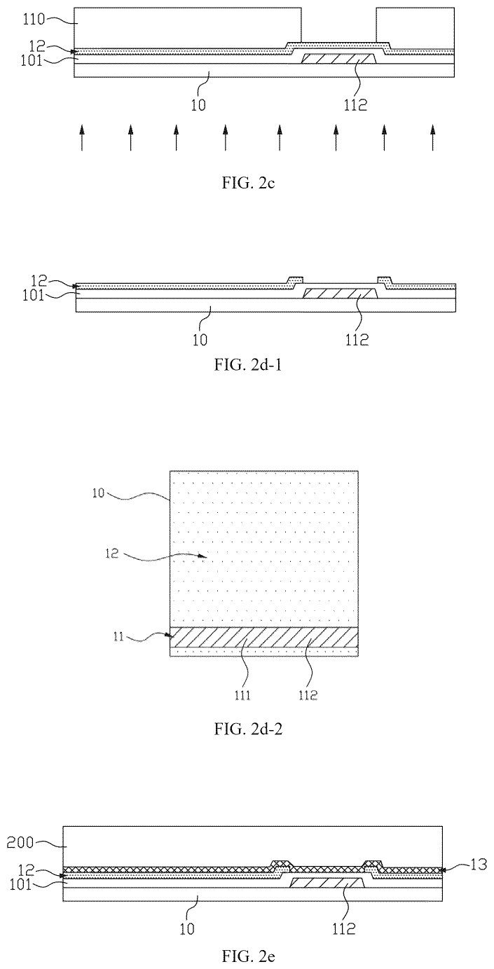

A second metal layer 15 (FIG. 2h) is provided above the first transparent conductive layer 12 and the semiconductor layer 13. The second metal layer 15 includes a data line 151, a source 152, and a second conductive portion 153. The data line 151 is electrically connected to the source 152, and at least one of the first conductive portion 122 and the second conductive portion 153 serves as a drain. Specifically, the second metal layer 15 can be made of metals, such as copper (Cu), silver (Ag), chromium (Cr), molybdenum (Mo), aluminum (Al), titanium (Ti), manganese (Mn), nickel (Ni), etc., or a combination of the above metals, such as Al/Mo, Cu/Mo, etc.

In this embodiment, the array substrate further includes a doped semiconductor layer 14 (FIG. 2h) arranged between the semiconductor layer 13 and the second metal layer 15. The doped semiconductor layer 14 includes a doped semiconductor pattern layer 141 formed by patterning. The doped semiconductor pattern layer 141 is disconnected in a channel region 142 of the active layer 131. The data line 151, the source 152 and the second conductive portion 153 correspond to the doped semiconductor pattern layer 141, that is, the projection of the data line 151, the source 152 and the second conductive portion 153 on the substrate 10 coincides with the doped semiconductor pattern layer 141. The doped semiconductor layer 14 is made of doped amorphous silicon (N+a-Si), which enables the source 152 and the drain to be better electrically connected to the active layer 131.

In this embodiment, the first electrode 121 is a pixel electrode, and the first electrode 121 is electrically connected to the first conductive portion 122.

Further, the array substrate also includes a second insulating layer 102 provided above the first insulating layer 101, and a second transparent conductive layer 16 provided above the second insulating layer 102. The second insulating layer 102 is provided with a contact hole H in the areas corresponding to the first electrode 121 and the second conductive portion 153. The second transparent conductive layer 16 includes a second electrode 161 and a third conductive portion 162. The second electrode 161 is a common electrode. The third conductive portion 162 and the first electrode 121 are both insulated from the second electrode 161, that is, the pixel electrode and the common electrode are insulated from each other, and the pixel electrode is located below the common electrode. The second electrode 161 has a comb-like structure in the area corresponding to the first electrode 121, which facilitates the formation of a horizontal electric field with the first electrode 121 to form a fringe field switching (FFS) display mode. The third conductive portion 162 electrically connects the first electrode 121 and the second conductive portion 153 through the contact hole H. In this embodiment, both the first conductive portion 122 and the second conductive portion 153 serve as the drain. By using both the first conductive portion 122 and the second conductive portion 153 as the drain, and connecting the first electrode 121 and the second conductive portion 153 electrically through the third conductive portion 162, the impedance of the drain can be reduced. Specifically, the material of the second insulating layer 102 is silicon oxide (SiOx), silicon nitride (SiNx), or a combination of both; the second transparent conductive layer 16 is made of transparent electrodes such as indium tin oxide (ITO) or indium zinc oxide (IZO). In other embodiments, a common electrode may not be provided on the array substrate, and the common electrode may be provided on the color film substrate 20 to form TN or VA display modes. Of course, the second transparent conductive layer 16 can also be omitted, the first conductive portion 122 can be directly used as the drain, and the first electrode 121 is electrically connected to the active layer 131 through the first conductive portion 122.

Specifically, the side of the substrate 10 facing the first metal layer 11 is the upward direction (or the front side), and the side of the substrate 10 away from the first metal layer 11 is the downward direction (or the back side).

FIGS. 2a to 2p are schematic diagrams of the manufacturing method for the array substrate in the first embodiment of the present invention. As shown in FIGS. 2a to 2p, this embodiment further provides a manufacturing method for an array substrate, and the manufacturing method is used to produce the above-mentioned array substrate. The manufacturing method includes:

As shown in FIGS. 2a-1 and 2a-2, a substrate 10 is provided. The substrate 10 can be made of materials such as glass, quartz, silicon, acrylic, or polycarbonate, etc. The substrate 10 can also be a flexible substrate, and suitable materials for the flexible substrate include, for example, polyether sulfone (PES), polyethylene naphthalate (PEN), polyethylene (PE), polyimide (PI), polyvinyl chloride (PVC), polyethylene terephthalate (PET), or a combination thereof.

A first metal layer 11 is formed above the substrate 10, and the first metal layer 11 is directly provided on the upper surface of the substrate 10. The first metal layer 11 is etched using a first masking process, such that the first metal layer 11 is patterned to form a scanning line 111 and a gate 112. The gate 112 is electrically connected to the scanning line 111. Specifically, the first metal layer 11 can be made of metals, such as copper (Cu), silver (Ag), chromium (Cr), molybdenum (Mo), aluminum (Al), titanium (Ti), manganese (Mn), nickel (Ni), etc., or a combination of the above metals, such as Al/Mo, Cu/Mo, etc.

A first insulating layer 101 covering the scanning line 111 and the gate 112 is formed above the substrate 10. The first insulating layer 101 is directly provided on the upper surfaces of the substrate 10 and the first metal layer 11 and covers the scanning line 111 and the gate 112. Specifically, the first insulating layer 101 is the gate insulating layer, and the material of the first insulating layer 101 is silicon oxide (SiOx), silicon nitride (SiNx), or a combination of both.

As shown in FIGS. 2b to 2d-2, a first transparent conductive layer 12 and a negative photoresist layer 100 are sequentially formed above the first insulating layer 101. Using the first metal layer 11 as a mask, the negative photoresist layer 100 is subjected to photolithography (exposure, development) from the side of the substrate 10 away from the negative photoresist layer 100 (i.e., the back side of the substrate 10) to remove the negative photoresist layer 100 in the areas corresponding to the scanning line 111 and the gate 112, such that the negative photoresist layer 100 is patterned to form a negative photoresist pattern layer 110. Using the negative photoresist pattern layer 110 as a shield, the first transparent conductive layer 12 is etched for the first time to remove the first transparent conductive layer 12 in the areas corresponding to the scanning line 111 and the gate 112. Specifically, the first transparent conductive layer 12 is made of metal oxide semiconductor, but a conductive treatment such as plasma treatment, ion bombardment, hydrogen (H2) doping, helium (He) doping, argon (Ar) doping, etc. is needed to be performed on the metal oxide semiconductor, such that a partial or all areas of the first transparent conductive layer 12 is made conductive. The impedance of the first transparent conductive layer 12 after conductive treatment is lower than that before conductive treatment, and is equivalent to the impedance of indium tin oxide (ITO) or indium zinc oxide (IZO). Preferably, the metal oxide semiconductor adopts transparent metal oxide semiconductor, such as indium zinc oxide (InZnO), indium gallium oxide (InGaO), indium tin oxide (InSnO), zinc tin oxide (ZnSnO), gallium tin oxide (GaSnO), gallium zinc oxide (GaZnO), indium gallium zinc oxide (IGZO), or indium gallium zinc tin oxide (IGZTO). Of course, in other embodiments, the first transparent conductive layer 12 can also be made of transparent electrodes such as indium tin oxide (ITO) or indium zinc oxide (IZO), so that the conductive treatment is not needed.

As shown in FIGS. 2e to 2g-2, a semiconductor layer 13 and a positive photoresist layer 200 are sequentially formed above the first insulating layer 101. Using the first metal layer 11 as a mask, the positive photoresist layer 200 is subjected to photolithography (exposure, development) from the side of the substrate 10 away from the positive photoresist layer 200 (i.e., the back side of the substrate 10), such that the positive photoresist layer 200 is patterned to form a positive photoresist pattern layer 210, and the positive photoresist pattern layer 210 corresponds to the scanning line 111 and the gate 112, that is, the positive photoresist layer 200 in the areas corresponding to the scanning line 111 and the gate 112 is left, and the projection of the scanning line 111 and the gate 112 on the substrate 10 coincides with the positive photoresist pattern layer 210. Using the positive photoresist pattern layer 210 as a shield, the semiconductor layer 13 is etched to form an active layer 131 corresponding to the scanning line 111 and the gate 112. That is, the projection of the scanning line 111 and the gate 112 on the substrate 10 coincides with the active layer 131. Specifically, only the active layer 131 corresponding to the gate 112 has switching characteristics, and the semiconductor layer 13 is made of amorphous silicon (a-Si).

Specifically, the first transparent conductive layer 12 can be etched for the first time, and then the semiconductor layer 13 and the positive photoresist layer 200 are sequentially formed above the first insulating layer 101; alternatively, the semiconductor layer 13 can be etched first to form the active layer 131, and then the first transparent conductive layer 12 and the negative photoresist layer 100 are sequentially formed above the first insulating layer 101. The sequence of the two etching processes can be adjusted.

In this embodiment, the array substrate further includes a doped semiconductor layer 14 located between the semiconductor layer 13 and the second metal layer 15. As shown in FIGS. 2h-2i, a doped semiconductor layer 14, a second metal layer 15 and a photoresist layer 300 are sequentially formed above the first transparent conductive layer 12 and the semiconductor layer 13. The second masking process uses a half tone mask 400 as a shield, the photoresist layer 300 is subjected to photolithography from the side of the half tone mask 400 away from the substrate 10 (i.e., the front side of the substrate 10), such that the photoresist layer 300 is patterned to form a first photoresist pattern layer 310. The first photoresist pattern layer 310 includes a completely photolithographed non-photoresist pattern area 311, a partially photolithographed semi-photoresist pattern layer 312, and an un-photolithographed full photoresist pattern layer 313. Specifically, the doped semiconductor layer 14 is made of doped amorphous silicon (N+a-Si), and the second metal layer 15 can be made of metals, such as copper (Cu), silver (Ag), chromium (Cr), molybdenum (Mo), aluminum (Al), titanium (Ti), manganese (Mn), nickel (Ni), etc., or a combination of the above metals, such as Al/Mo, Cu/Mo, etc.

The photoresist layer 300 uses positive photoresist, and the half tone mask 400 includes a transparent region 410, a semi-transparent region 420, and a non-transparent region 430. The photoresist layer 300 in the area corresponding to the transparent region 410 is completely etched away to form the non-photoresist pattern area 311, the photoresist layer 300 in the area corresponding to the semi-transparent region 420 is partially etched away to form the semi-photoresist pattern layer 312, and the photoresist layer 300 in the area corresponding to the non-transparent region 430 is not photolithographed to form the full photoresist pattern layer 313. Of course, the photoresist layer 300 can also use negative photoresist, and the half tone mask 400 only needs to switch the patterns of the transparent region 410 and the non-transparent region 430, such that the photoresist layer 300 in the area corresponding to the transparent region 410 is not etched away to form the full photoresist pattern layer 313, the photoresist layer 300 in the area corresponding to the semi-transparent region 420 is partially etched away to form the semi-photoresist pattern layer 312, and the photoresist layer 300 in the area corresponding to the non-transparent region 430 is completely etched away to form the non-photoresist pattern area 311.

As shown in FIGS. 2j-1 and 2j-2, using the first photoresist pattern layer 310 as a shield, the second metal layer 15 is etched for the first time, the doped semiconductor layer 14 is etched for the first time, and the first transparent conductive layer 12 is etched for the second time. The first transparent conductive layer 12 is patterned to form a first electrode 121 and a first conductive portion 122, wherein the first conductive portion 122 is electrically connected to the active layer 131. In this embodiment, the first electrode 121 is a pixel electrode, and the first electrode 121 is electrically connected to the first conductive portion 122, that is, the first conductive portion 122 serves as a drain.

As shown in FIGS. 2k to 2l-2, a photoresist ashing process is used to remove the semi-photoresist pattern layer 312 and retain a portion of the full photoresist pattern layer 313, such that the first photoresist pattern layer 310 is formed into a second photoresist pattern layer 320. Using the second photoresist pattern layer 320 as a shield, the second metal layer 15 is etched for the second time, and the doped semiconductor layer 14 is etched for the second time. The second metal layer 15 forms a data line 151, a source 152, and a second conductive portion 153, while the first electrode 121 and the active layer 131 in the channel region 142 are exposed, and the data line 151 is electrically connected to the source 152. The doped semiconductor layer 14 is patterned to form a doped semiconductor pattern layer 141, and the doped semiconductor pattern layer 141 is disconnected in the channel region 142. The data line 151, the source 152 and the second conductive portion 153 correspond to the doped semiconductor pattern layer 141, that is, the projection of the data line 151, the source 152 and the second conductive portion 153 on the substrate 10 coincides with the doped semiconductor pattern layer 141. By forming the doped semiconductor pattern layer 141, the source and the drain can be better electrically connected to the active layer 131, and the doped semiconductor layer 14 and the first transparent conductive layer 12 retained under the data line 151 can reduce the impedance of the data line 151. Specifically, the first electrode 121 and the channel region 142 of the active layer 131 correspond to the semi-photoresist pattern layer 312, while the data line 151, the source 152 and the second conductive portion 153 correspond to the full photoresist pattern layer 313.

As shown in FIGS. 2m-1 and 2m-2, in this embodiment, the first transparent conductive layer 12 is made of metal oxide semiconductor. After the second metal layer 15 is etched for the second time, the first transparent conductive layer 12 is then subjected to conductive treatment, so that the first electrode 121 is made conductive. For example, plasma treatment, ion bombardment, hydrogen (H2) doping, helium (He) doping, or argon (Ar) doping can be used to make a partial or all areas of the first transparent conductive layer 12 conductive. Preferably, the first transparent conductive layer 12 is subjected to conductive treatment using a hydrogen doping process, and the active layer 131 exposed in the channel region 142 is also subjected to hydrogen channel treatment simultaneously. When the doped semiconductor layer 14 is etched for the second time to form the channel, a hydrogen doping process is needed to cause the active layer 131 exposed in the channel region 142 to be subjected to hydrogen channel treatment for ensuring that the active layer 131 has good switching characteristics. Therefore, after the second metal layer 15 is etched for the second time, the hydrogen doping process can not only perform hydrogen channel treatment to the active layer 131 exposed in the channel region 142, but also make the first transparent conductive layer 12 conductive, thereby reducing the steps of the manufacturing process.

As shown in FIGS. 2n to 20, a second insulating layer 102 is formed above the first insulating layer 101, and the second insulating layer 102 is etched using a third masking process, such that a contact hole H is formed in the areas corresponding to the first electrode 121 and the second conductive portion 153. Specifically, the material of the second insulating layer 102 is silicon oxide (SiOx), silicon nitride (SiNx), or a combination of both.

As shown in FIGS. 2p-1 and 2p-2, a second transparent conductive layer 16 is formed above the second insulating layer 102, and the second transparent conductive layer 16 is etched using a fourth masking process, such that the second transparent conductive layer 16 is patterned to form a second electrode 161 and a third conductive portion 162. The second electrode 161 is a common electrode. The third conductive portion 162 and the first electrode 121 are both insulated from the second electrode 161, that is, the pixel electrode and the common electrode are insulated from each other, and the pixel electrode is located below the common electrode. The second electrode 161 has a comb-like structure in the area corresponding to the first electrode 121, which facilitates the formation of a horizontal electric field with the first electrode 121 to form a fringe field switching (FFS) display mode. The third conductive portion 162 electrically connects the first electrode 121 and the second conductive portion 153 through the contact hole H. In this embodiment, both the first conductive portion 122 and the second conductive portion 153 serve as the drain. By using both the first conductive portion 122 and the second conductive portion 153 as the drain, and connecting the first electrode 121 and the second conductive portion 153 electrically through the third conductive portion 162, the impedance of the drain can be reduced. Specifically, the second transparent conductive layer 16 is made of transparent electrodes such as indium tin oxide (ITO) or indium zinc oxide (IZO). In other embodiments, a common electrode may not be provided on the array substrate, and the common electrode may be provided on the color film substrate 20 to form TN or VA display modes. Of course, the second transparent conductive layer 16 can also be omitted, the first conductive portion 122 can be directly used as the drain, and the first electrode 121 is electrically connected to the active layer 131 through the first conductive portion 122.

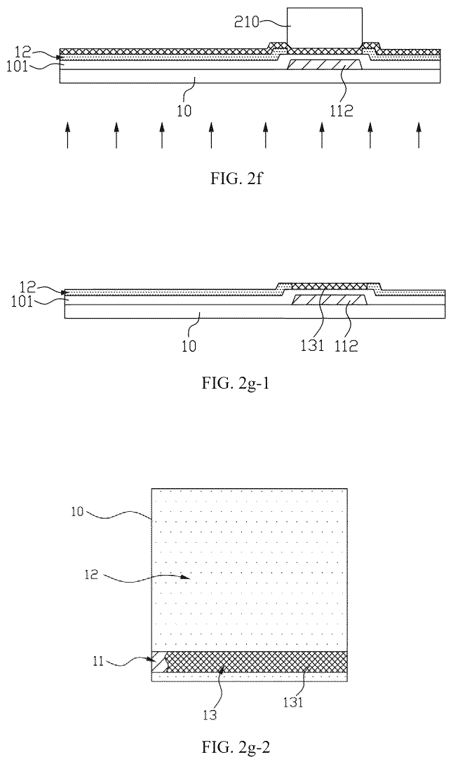

FIG. 3 is a schematic cross-sectional view of the display panel in the first embodiment of the present invention. As shown in FIG. 3, the present invention also provides a display panel including an array substrate as described above, an opposing substrate 20 arranged opposite to the array substrate, and a liquid crystal layer 30 arranged between the array substrate and the opposing substrate 20. An upper polarizer 41 is provided on the opposing substrate 20, and a lower polarizer 42 is provided on the array substrate. The transmission axis of the upper polarizer 41 is perpendicular to that of the lower polarizer 42. Specifically, the liquid crystal molecules in the liquid crystal layer 30 adopt positive liquid crystal molecules (i.e., liquid crystal molecules with positive dielectric anisotropy). In the initial state, the positive liquid crystal molecules are in a lying posture, and the alignment direction of the positive liquid crystal molecules near the opposing substrate 20 is parallel to that of the positive liquid crystal molecules near the array substrate. It can be understood that the array substrate and the counter substrate 20 also have an alignment layer on the side facing the liquid crystal layer 30 so as to align the positive liquid crystal molecules in the liquid crystal layer 30.

In this embodiment, the opposing substrate 20 is a color film substrate, and a black matrix 21 and color resist layers 22 are provided on the opposing substrate 20. The black matrix 21 corresponds to the scanning line 111, the data line 151, the thin film transistor, and the peripheral non-display area, and the black matrix 21 separates multiple color resist layers 22. The color resist layers 22 includes color resist materials of red (R), green (G), and blue (B) colors, and corresponds to the formation of red (R), green (G), and blue (B) sub pixels.

### Second Embodiment

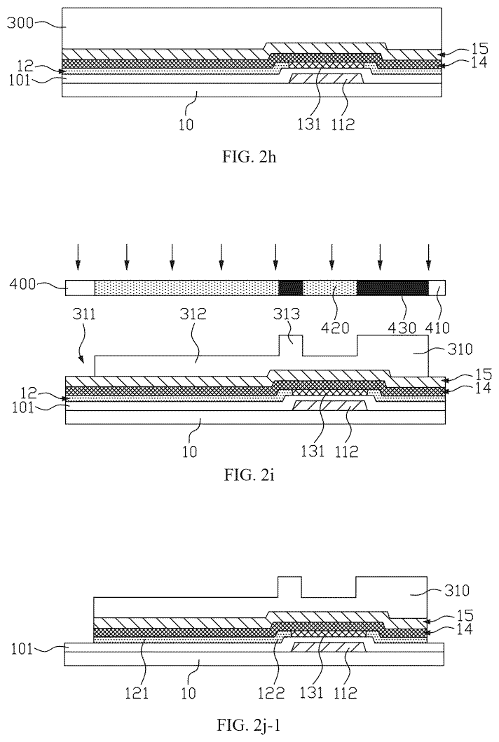

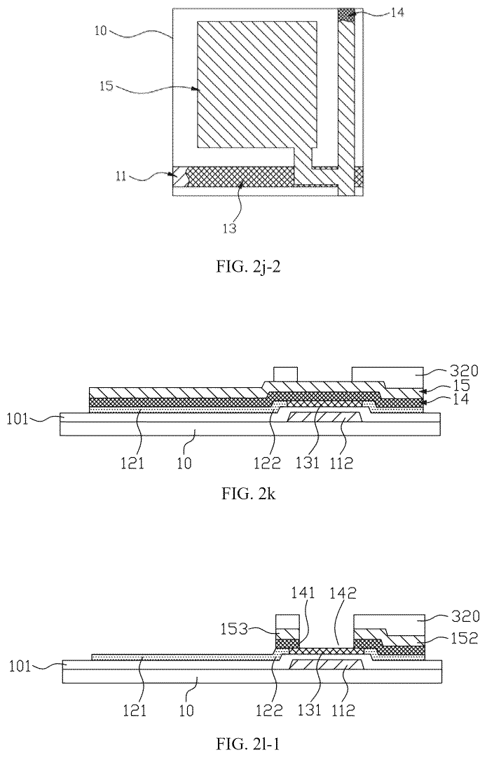

FIG. 4 is a schematic cross-sectional view of the array substrate in the second embodiment of the present invention. FIG. 5 is a schematic plan view of the array substrate in the second embodiment of the present invention. As shown in FIGS. 4 and 5, the array substrate provided in the second embodiment of the present invention is basically the same as the array substrate in the first embodiment (FIG. 1), except that in this embodiment:

The array substrate further includes a second insulating layer 102 provided above the first insulating layer 101, and a second transparent conductive layer 16 provided above the second insulating layer 102. The second transparent conductive layer 16 includes a second electrode 161. The second electrode 161 is a common electrode, the first electrode 121 and the second electrode 161 are insulated from each other, that is, the pixel electrode and the common electrode are insulated from each other, and the pixel electrode is located below the common electrode. The second electrode 161 has a comb-like structure in the area corresponding to the first electrode 121, which facilitates the formation of a horizontal electric field with the first electrode 121 to form a fringe field switching (FFS) display mode. In this embodiment, the first conductive portion 122 is directly used as the drain, and the first electrode 121 is connected to the active layer 131 through the first conductive portion 122. Therefore, the second transparent conductive layer 16 does not need to form the third conductive portion 162, and the second insulating layer 102 does not need to be perforated in the areas corresponding to the first electrode 121 and the second conductive portion 153, thereby simplifying the manufacturing process.

Compared to the first embodiment, in this embodiment, the first conductive portion 122 is directly used as the drain, and the impedance of the drain is relatively high. However, the second transparent conductive layer 16 does not need to form the third conductive portion 162, and the second insulating layer 102 also does not need to be perforated in the areas corresponding to the first electrode 121 and the second conductive portion 153, thereby simplifying the manufacturing process.

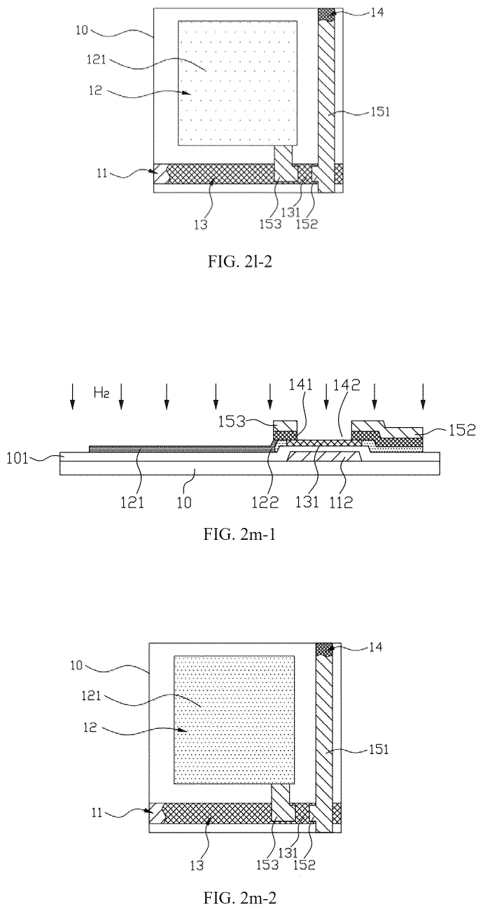

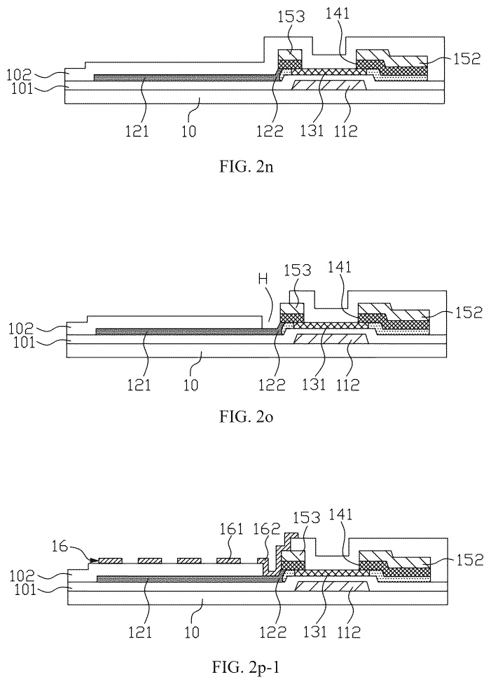

FIG. 6 is a first cross-sectional schematic diagram of the manufacturing method for the array substrate in the second embodiment of the present invention. FIG. 7 is a second cross-sectional schematic diagram of the manufacturing method for the array substrate in the second embodiment of the present invention. As shown in FIGS. 6 to 7, the manufacturing method provided in the second embodiment of the present invention is basically the same as the manufacturing method in the first embodiment (FIGS. 2a to 2p), except that in this embodiment:

The first transparent conductive layer 12 is made of metal oxide semiconductor. The manufacturing method further includes: before forming the second metal layer 15, the first transparent conductive layer 12 is first subjected to conductive treatment; after the second metal layer 15 is etched for the second time, the active layer 131 exposed in the channel region 142 is subjected to hydrogen channel treatment using a hydrogen doping process. In this embodiment, since a doped semiconductor layer 14 is also provided before forming the second metal layer 15, therefore, the first transparent conductive layer 12 is required to be first subjected to conductive treatment before forming the doped semiconductor layer 14.

Specifically, as shown in FIG. 6 and referring to FIG. 2b, after forming the first transparent conductive layer 12 above the first insulating layer 101, the first transparent conductive layer 12 is then subjected to conductive treatment, and a negative photoresist layer 100 is then formed on the surface of the first transparent conductive layer 12. Alternatively, referring to FIG. 2d-1, after the first transparent conductive layer 12 is etched for the first time and the negative photoresist pattern layer 110 is removed, the first transparent conductive layer 12 is then subjected to conductive treatment, and then, a semiconductor layer 13 and a positive photoresist layer 200 are sequentially formed above the first insulating layer 101. Alternatively, as shown in FIG. 7 and referring to FIG. 2g-1, after the semiconductor layer 13 is etched, the first transparent conductive layer 12 is then subjected to conductive treatment. In short, before forming the second metal layer 15 and the doped semiconductor layer 14, the first transparent conductive layer 12 is first subjected to conductive treatment, so that the first transparent conductive layer 12 is wholly made conductive, that is, the first conductive portion 122 can also be made conductive to reduce the impedance of the first conductive portion 122. Of course, in other embodiments, the first transparent conductive layer 12 can also be made of transparent electrodes such as indium tin oxide (ITO) or indium zinc oxide (IZO), so that the conductive treatment is not needed.

Further, referring to FIGS. 2n-20, a second insulating layer 102 is formed above the first insulating layer 101. The second insulating layer 102 does not need to be perforated in the areas corresponding to the first electrode 121 and the second conductive portion 153. Specifically, the material of the second insulating layer 102 is silicon oxide (SiOx), silicon nitride (SiNx), or a combination of both.

Referring to FIGS. 2p-1 and 2p-2, a second transparent conductive layer 16 is formed above the second insulating layer 102, and the second transparent conductive layer 16 is etched, such that the second transparent conductive layer 16 is patterned to form a second electrode 161. The second electrode 161 is a common electrode, the first electrode 121 and the second electrode 161 are insulated from each other, that is, the pixel electrode and the common electrode are insulated from each other, and the pixel electrode is located below the common electrode. The second electrode 161 has a comb-like structure in the area corresponding to the first electrode 121, which facilitates the formation of a horizontal electric field with the first electrode 121 to form a fringe field switching (FFS) display mode. In this embodiment, the first conductive portion 122 is directly used as the drain, and the first electrode 121 is connected to the active layer 131 through the first conductive portion 122. Therefore, the second transparent conductive layer 16 does not need to form the third conductive portion 162, and the second insulating layer 102 does not need to be perforated in the areas corresponding to the first electrode 121 and the second conductive portion 153, thereby simplifying the manufacturing process.

Compared to the first embodiment, in this embodiment, the first conductive portion 122 is directly used as the drain, and the impedance of the drain is relatively high. However, the second transparent conductive layer 16 does not need to form the third conductive portion 162, and the second insulating layer 102 also does not need to be perforated in the areas corresponding to the first electrode 121 and the second conductive portion 153, thereby simplifying the manufacturing process. Further, before forming the second metal layer 15 and the doped semiconductor layer 14, the first transparent conductive layer 12 is first subjected to conductive treatment, so that the first transparent conductive layer 12 is wholly made conductive, that is, the first conductive portion 122 can also be made conductive to reduce the impedance of the first conductive portion 122.

The display panel provided in the second embodiment of the present invention is basically the same as the display panel in the first embodiment (FIG. 3), except that in this embodiment, the display panel includes an array substrate as described above, an opposing substrate 20 arranged opposite to the array substrate, and a liquid crystal layer 30 arranged between the array substrate and the opposing substrate 20.

Specifically, the array substrate also includes a second insulating layer 102 provided above the first insulating layer 101, and a second transparent conductive layer 16 provided above the second insulating layer 102. The second transparent conductive layer 16 includes a second electrode 161. The second electrode 161 is a common electrode, the first electrode 121 and the second electrode 161 are insulated from each other, that is, the pixel electrode and the common electrode are insulated from each other, and the pixel electrode is located below the common electrode. The second electrode 161 has a comb-like structure in the area corresponding to the first electrode 121, which facilitates the formation of a horizontal electric field with the first electrode 121 to form a fringe field switching (FFS) display mode. In this embodiment, the first conductive portion 122 is directly used as the drain, and the first electrode 121 is connected to the active layer 131 through the first conductive portion 122. Therefore, the second transparent conductive layer 16 does not need to form the third conductive portion 162, and the second insulating layer 102 does not need to be perforated in the areas corresponding to the first electrode 121 and the second conductive portion 153, thereby simplifying the manufacturing process.

A person skilled in the art should understand that the remaining structures and working principles of this embodiment are the same as those of the first embodiment, and will not be repeated here.

### Third Embodiment

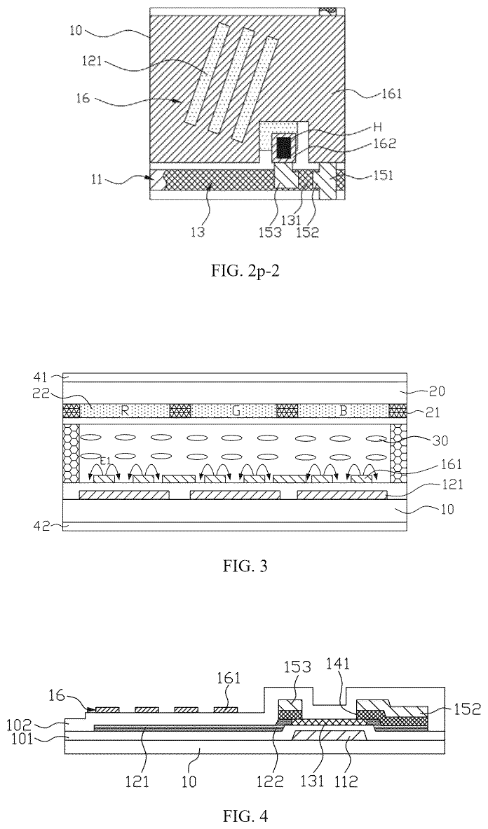

FIG. 8 is a schematic cross-sectional view of the array substrate in the third embodiment of the present invention. As shown in FIG. 8, the array substrate provided in the third embodiment of the present invention is basically the same as the array substrates in the first embodiment (FIG. 1) and the second embodiment (FIG. 4), except that in this embodiment:

The first conductive portion 122 and the second conductive portion 153 are electrically connected, both the first conductive portion 122 and the second conductive portion 153 serve as the drain, and the first electrode 121 is electrically connected to the active layer 131 through the first conductive portion 122 and the second conductive portion 153.

Further, the array substrate also includes a second insulating layer 102 provided above the first insulating layer 101, and a second transparent conductive layer 16 provided above the second insulating layer 102. The second transparent conductive layer 16 includes a second electrode 161. The second electrode 161 is a common electrode, the first electrode 121 and the second electrode 161 are insulated from each other, that is, the pixel electrode and the common electrode are insulated from each other, and the pixel electrode is located below the common electrode. The second electrode 161 has a comb-like structure in the area corresponding to the first electrode 121, which facilitates the formation of a horizontal electric field with the first electrode 121 to form a fringe field switching (FFS) display mode. Since the first conductive portion 122 and the second conductive portion 153 are directly electrically connected, the second transparent conductive layer 16 does not need to form the third conductive portion 162, and the second insulating layer 102 does not need to be perforated in the areas corresponding to the first electrode 121 and the second conductive portion 153, thereby simplifying the manufacturing process.

In this embodiment, by directly electrically connecting the first conductive portion 122 and the second conductive portion 153, the second transparent conductive layer 16 does not need to form the third conductive portion 162, and the second insulating layer 102 also does not need to be perforated in the areas corresponding to the first electrode 121 and the second conductive portion 153. This simplifies the manufacturing process and has little effect on the impedance of the drain.

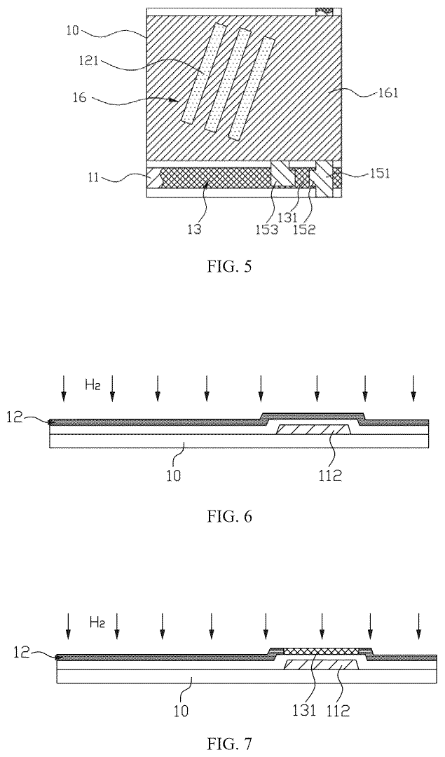

FIGS. 9a-9b are schematic cross-sectional views of the manufacturing method for the array substrate in the third embodiment of the present invention. As shown in FIGS. 9a-9b, the manufacturing method provided in the third embodiment of the present invention is basically the same as the manufacturing methods in the first embodiment (FIGS. 2a to 2p) and the second embodiment (FIGS. 5 to 7), except that in this embodiment:

As shown in FIG. 9a and referring to FIGS. 2e to 2g-2, after forming the semiconductor layer 13 and before forming the positive photoresist layer 200, a doped semiconductor layer 14 is formed above the semiconductor layer 13, that is, the semiconductor layer 13, the doped semiconductor layer 14 and the positive photoresist layer 200 are sequentially formed above the first insulating layer 101. Using the first metal layer 11 as a mask, the positive photoresist layer 200 is subjected to photolithography (exposure, development) from the side of the substrate 10 away from the positive photoresist layer 200 (i.e., the back side of the substrate 10), such that the positive photoresist layer 200 is patterned to form a positive photoresist pattern layer 210, and the positive photoresist pattern layer 210 corresponds to the scanning line 111 and the gate 112, that is, the positive photoresist layer 200 in the areas corresponding to the scanning line 111 and the gate 112 is left. Using the positive photoresist pattern layer 210 as a shield, the semiconductor layer 13 is etched, and the doped semiconductor layer 14 is etched for the first time. The semiconductor layer 13 forms an active layer 131 corresponding to the scanning line 111 and the gate 112. Before forming the second metal layer 15, by etching the doped semiconductor layer 14 for the first time with the positive photoresist pattern layer 210 as a shield, the second metal layer 15 can directly contact the first transparent conductive layer 12 when thereafter forming the second metal layer 15.

As shown in FIG. 9b and referring to FIG. 2l-1, after the second metal layer 15 is etched for the second time, the doped semiconductor layer 14 is etched for the second time by using the second photoresist pattern layer 320 as a shield. The doped semiconductor layer 14 forms a doped semiconductor pattern layer 141, the doped semiconductor pattern layer 141 is disconnected in the channel region 142, and the first conductive portion 122 and the second conductive portion 153 are electrically connected.

Further, referring to FIGS. 2n-20, a second insulating layer 102 is formed above the first insulating layer 101, and the second insulating layer 102 does not need to be perforated in the areas corresponding to the first electrode 121 and the second conductive portion 153. Specifically, the material of the second insulating layer 102 is silicon oxide (SiOx), silicon nitride (SiNx), or a combination of both.

Referring to FIGS. 2p-1 and 2p-2, a second transparent conductive layer 16 is formed above the second insulating layer 102, and the second transparent conductive layer 16 is etched, such that the second transparent conductive layer 16 is patterned to form a second electrode 161. The second electrode 161 is a common electrode, the first electrode 121 and the second electrode 161 are insulated from each other, that is, the pixel electrode and the common electrode are insulated from each other, and the pixel electrode is located below the common electrode. The second electrode 161 has a comb-like structure in the area corresponding to the first electrode 121, which facilitates the formation of a horizontal electric field with the first electrode 121 to form a fringe field switching (FFS) display mode. In this embodiment, the first conductive portion 122 and the second conductive portion 153 are used as the drain, and the first conductive portion 122 and the second conductive portion 153 are directly electrically connected. The first electrode 121 is electrically connected to the active layer 131 through the first conductive portion 122 and the second conductive portion 153. Therefore, the second transparent conductive layer 16 does not need to form the third conductive portion 162, and the second insulating layer 102 does not need to be perforated in the areas corresponding to the first electrode 121 and the second conductive portion 153, thereby simplifying the manufacturing process.

In this embodiment, when etching the semiconductor layer 13, the doped semiconductor layer 14 is etched for the first time by using the positive photoresist pattern layer 210 as a shield, so that the first conductive portion 122 and the second conductive portion 153 can be directly electrically connected. Therefore, the second transparent conductive layer 16 does not need to form the third conductive portion 162, and the second insulating layer 102 also does not need to be perforated in the areas corresponding to the first electrode 121 and the second conductive portion 153. This simplifies the manufacturing process and has little effect on the impedance of the drain.

The display panel provided in the third embodiment of the present invention is basically the same as the display panels in the first embodiment (FIG. 3) and the second embodiment, except that in this embodiment, the display panel includes an array substrate as described above, an opposing substrate 20 arranged opposite to the array substrate, and a liquid crystal layer 30 arranged between the array substrate and the opposing substrate 20.

Specifically, the array substrate also includes a second insulating layer 102 provided above the first insulating layer 101, and a second transparent conductive layer 16 provided above the second insulating layer 102. The second transparent conductive layer 16 includes a second electrode 161. The second electrode 161 is a common electrode, the first electrode 121 and the second electrode 161 are insulated from each other, that is, the pixel electrode and the common electrode are insulated from each other, and the pixel electrode is located below the common electrode. The second electrode 161 has a comb-like structure in the area corresponding to the first electrode 121, which facilitates the formation of a horizontal electric field with the first electrode 121 to form a fringe field switching (FFS) display mode. Since the first conductive portion 122 and the second conductive portion 153 are directly electrically connected, the first conductive portion 122 and the second conductive portion 153 together serve as the drain, and the first electrode 121 is electrically connected to the active layer 131 through the first conductive portion 122 and the second conductive portion 153, therefore, the second transparent conductive layer 16 does not need to form the third conductive portion 162, and the second insulating layer 102 also does not need to be perforated in the areas corresponding to the first electrode 121 and the second conductive portion 153, thereby simplifying the manufacturing process.

A person skilled in the art should understand that the remaining structures and working principles of this embodiment are the same as those of the first and second embodiments, and will not be repeated here.

### Fourth Embodiment

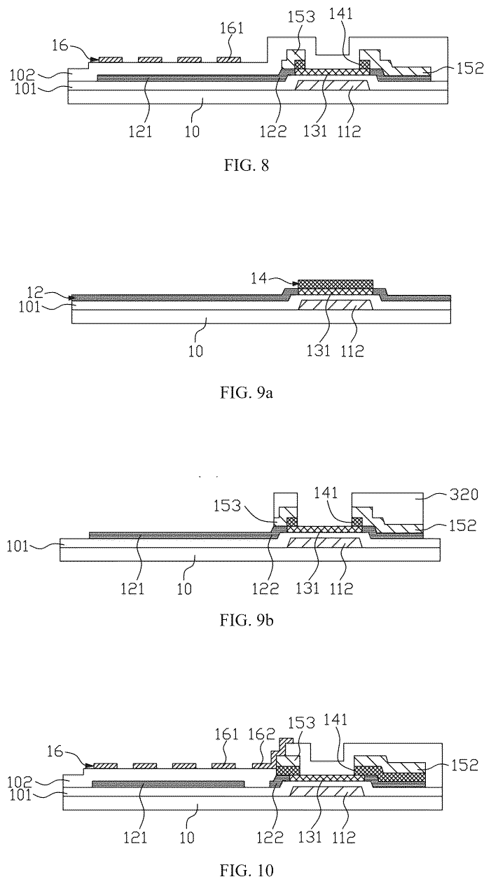

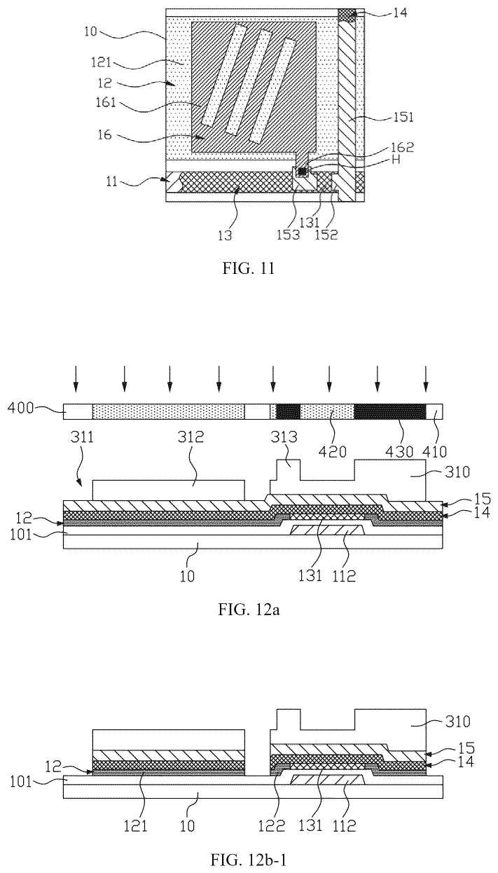

FIG. 10 is a schematic cross-sectional view of the array substrate in the fourth embodiment of the present invention. FIG. 11 is a schematic plan view of the array substrate in the fourth embodiment of the present invention. As shown in FIGS. 10 and 11, the array substrate provided in the fourth embodiment of the present invention is basically the same as the array substrates in the first embodiment (FIG. 1), the second embodiment (FIG. 4), and the third embodiment (FIG. 8), except that in this embodiment:

The first electrode 121 is a common electrode, and the first electrode 121 and the first conductive portion 122 are insulated from each other. The array substrate further includes a second insulating layer 102 provided above the first insulating layer 101, and a second transparent conductive layer 16 provided above the second insulating layer 102. The second insulating layer 102 is provided with a contact hole H in the area corresponding to the second conductive portion 153. The second transparent conductive layer 16 includes a second electrode 161 and a third conductive portion 162. The second electrode 161 is a pixel electrode, and the first electrode 121 and the second electrode 161 are insulated from each other, that is, the pixel electrode and the common electrode are insulated from each other, and the pixel electrode is located above the common electrode. The third conductive portion 162 is electrically connected to the second electrode 161, and the third conductive portion 162 is electrically connected to the second conductive portion 153 through the contact hole H. In this embodiment, the second conductive portion 153 serves as the drain.

In this embodiment, the first electrode 121 is a common electrode, and the second electrode 161 is a pixel electrode, so that the pixel electrode is located above the common electrode to form another fringe field switching (FFS) display mode.

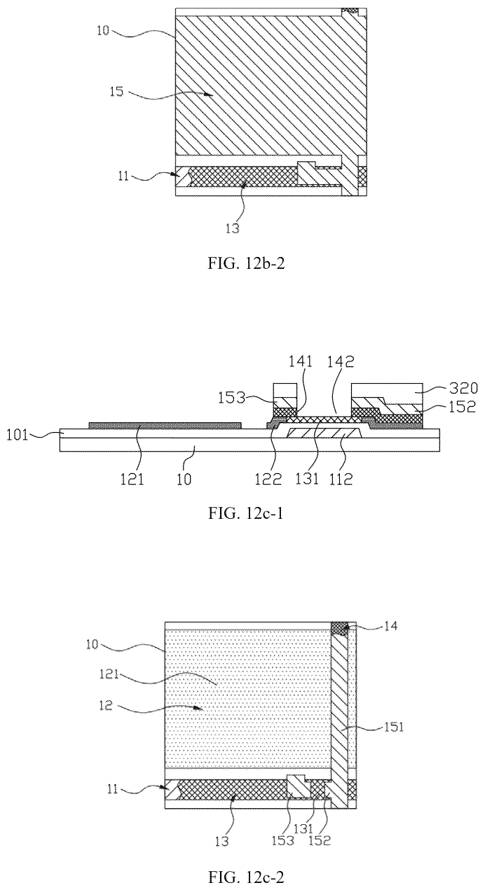

FIGS. 12a to 12c are schematic diagrams of the manufacturing method for the array substrate in the fourth embodiment of the present invention. As shown in FIGS. 12a to 12c, the manufacturing method provided in the fourth embodiment of the present invention is basically the same as the manufacturing methods in the first embodiment (FIGS. 2a to 2p), the second embodiment (FIGS. 5 to 7) and the third embodiment (FIGS. 9a to 9b), except that in this embodiment:

The manufacturing method further includes:

As shown in FIG. 12a, and referring to FIGS. 2h-2i, a doped semiconductor layer 14, a second metal layer 15 and a photoresist layer 300 are sequentially formed above the first transparent conductive layer 12 and the semiconductor layer 13. The second masking process uses a half tone mask 400 as a shield, the photoresist layer 300 is subjected to photolithography from the side of the half tone mask 400 away from the substrate 10 (i.e., the front side of the substrate 10), such that the photoresist layer 300 is patterned to form a first photoresist pattern layer 310. The first photoresist pattern layer 310 includes a completely photolithographed non-photoresist pattern area 311, a partially photolithographed semi-photoresist pattern layer 312, and an un-photolithographed full photoresist pattern layer 313.

Specifically, the pattern of the halftone mask plate 400 in this embodiment is different from that of the halftone mask plate 400 in the first embodiment. Specifically, in this embodiment, a transparent region 410 is provided between the semi-transparent region 420 that corresponds to the first electrode 121 and the non-transparent region 430 that corresponds to the first conductive portion 122. Therefore, the first photoresist pattern layer 310 has a non-photoresist pattern area 311 provided between the semi-photoresist pattern layer 312 that corresponds to the first electrode 121 and the full photoresist pattern layer 313 that corresponds to the first conductive portion 122, so that when the second metal layer 15 is etched for the first time with the first photoresist pattern layer 310 as a shield, the first electrode 121 and the first conductive portion 122 are disconnected.

As shown in FIGS. 12b-1 and 14a, and referring to FIGS. 2j-1 and 2j-2, with the first photoresist pattern layer 310 as a shield, the second metal layer 15 is etched for the first time, the doped semiconductor layer 14 is etched for the first time, and the first transparent conductive layer 12 is etched for the second time. The first transparent conductive layer 12 is patterned to form a first electrode 121 and a first conductive portion 122, wherein the first conductive portion 122 is electrically connected to the active layer 131. In this embodiment, the first electrode 121 is a common electrode, and the first electrode 121 and the first conductive portion 122 are insulated from each other.

As shown in FIGS. 12c-1 and 14b, and referring to FIGS. 2k-21 and 21-2, a photoresist ashing process is used to remove the semi-photoresist pattern layer 312 and retain a portion of the full photoresist pattern layer 313, such that the first photoresist pattern layer 310 is formed into a second photoresist pattern layer 320. Using the second photoresist pattern layer 320 as a shield, the second metal layer 15 is etched for the second time, and the doped semiconductor layer 14 is etched for the second time. The second metal layer 15 forms a data line 151, a source 152, and a second conductive portion 153, while the first electrode 121 and the active layer 131 in the channel region 142 are exposed, and the data line 151 is electrically connected to the source 152.

Referring to FIGS. 2n-2o, a second insulating layer 102 is formed above the first insulating layer 101, and the second insulating layer 102 is etched to form a contact hole H in the area corresponding to the second conductive portion 153. Specifically, the material of the second insulating layer 102 is silicon oxide (SiOx), silicon nitride (SiNx), or a combination of both.

Referring to FIGS. 2p-1 and 2p-2, a second transparent conductive layer 16 is formed above the second insulating layer 102, and the second transparent conductive layer 16 is etched, such that the second transparent conductive layer 16 is patterned to form a second electrode 161 and a third conductive portion 162. The second electrode 161 is a pixel electrode, the first electrode 121 (common electrode) is insulated from the second electrode 161 (pixel electrode), and the pixel electrode is located above the common electrode. The third conductive portion 162 is electrically connected to the second electrode 161, and the third conductive portion 162 is electrically connected to the second conductive portion 153 through the contact hole H. In this embodiment, the second conductive portion 153 serves as the drain.

In this embodiment, the first electrode 121 is a common electrode, and the second electrode 161 is a pixel electrode, so that the pixel electrode is located above the common electrode to form another fringe field switching (FFS) display mode.

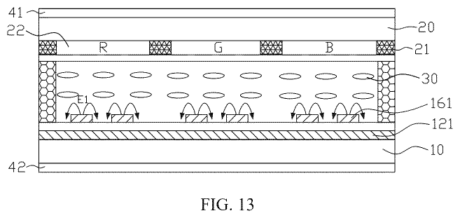

FIG. 13 is a schematic cross-sectional view of the display panel in the fourth embodiment of the present invention. As shown in FIG. 13, the display panel provided in the fourth embodiment of the present invention is basically the same as the display panels in the first embodiment (FIG. 3), the second embodiment, and the third embodiment, except that in this embodiment, the display panel includes an array substrate as described above, an opposing substrate 20 arranged opposite to the array substrate, and a liquid crystal layer 30 arranged between the array substrate and the opposing substrate 20. Specifically, the first electrode 121 on the array substrate is a common electrode, and the first electrode 121 and the first conductive portion 122 are insulated from each other, the second electrode 161 is a pixel electrode, and the pixel electrode is located above the common electrode to form another fringe field switching (FFS) display mode.

The array substrate further includes a second insulating layer 102 provided above the first insulating layer 101, and a second transparent conductive layer 16 provided above the second insulating layer 102. The second insulating layer 102 is provided with a contact hole H in the area corresponding to the second conductive portion 153. The second transparent conductive layer 16 includes a second electrode 161 and a third conductive portion 162. The second electrode 161 is a pixel electrode, and the first electrode 121 and the second electrode 161 are insulated from each other, that is, the pixel electrode and the common electrode are insulated from each other, and the pixel electrode is located above the common electrode. The third conductive portion 162 is electrically connected to the second electrode 161, and the third conductive portion 162 is electrically connected to the second conductive portion 153 through the contact hole H. In this embodiment, the second conductive portion 153 serves as the drain.

A person skilled in the art should understand that the remaining structures and working principles of this embodiment are the same as those of the first, second and third embodiments, and will not be repeated here.

In this description, the directional terms such as “up”, “down”, “left”, “right”, “front” and “back” are defined by the positions of the structures in the drawings and the positions between the structures, and are only for clearly and conveniently expressing technical solutions. It should be understood that the use of the directional terms should not limit the scope of protection claimed in this invention. It should also be understood that the terms “first” and “second”, etc. used herein are only used to distinguish elements, and are not used to limit the number and order.

The above descriptions are only preferred embodiments of the present invention, and do not limit the present invention in any form. Although the present invention has been disclosed above with preferred embodiments, it is not intended to limit the present invention. The persons skilled in the art may make some changes or modifications by using the technical content disclosed above, and if they do not depart from the technical content of the present invention, any simple modifications, equivalent changes and modifications made to the above embodiments still fall within the protection scope of the technical solution of the present invention.

### INDUSTRIAL APPLICABILITY

By using the first metal layer as a mask and employing backside exposure, and alternating the use of negative and positive photoresists, the first transparent conductive layer is etched for the first time and the semiconductor layer is etched. Then, the first transparent conductive layer is etched for the second time and the second metal layer is etched twice by using a half-tone mask, thereby reducing the number of masks, simplifying the manufacturing process, and reducing the manufacturing costs; moreover, after etching the second metal layer twice, the first transparent conductive layer will still be retained under the data line, the source, and the second conductive portion, thereby reducing the impedance of the data line, the source, and the second conductive portion.

1. A manufacturing method for an array substrate, comprising:
providing a substrate;
forming a first metal layer above the substrate, and the first metal layer being etched such that the first metal layer is patterned to form a scanning line and a gate, wherein the gate is electrically connected to the scanning line;
forming a first insulating layer covering the scanning line and the gate above the substrate;
forming sequentially a first transparent conductive layer and a negative photoresist layer above the first insulating layer, and using the first metal layer as a mask, the negative photoresist layer being subjected to photolithography treatment from the side of the substrate away from the negative photoresist layer to remove the negative photoresist layer in the areas corresponding to the scanning line and the gate, the negative photoresist layer being patterned to form a negative photoresist pattern layer, and using the negative photoresist pattern layer as a shield, the first transparent conductive layer being etched for the first time to remove the first transparent conductive layer in the areas corresponding to the scanning line and the gate;
forming sequentially a semiconductor layer and a positive photoresist layer above the first insulating layer, and using the first metal layer as a mask, the positive photoresist layer being subjected to photolithography from the side of the substrate away from the positive photoresist layer, the positive photoresist layer being patterned to form a positive photoresist pattern layer, the positive photoresist pattern layer corresponding to the scanning line and the gate, and using the positive photoresist pattern layer as a shield, the semiconductor layer being etched to form an active layer corresponding to the scanning line and the gate;
forming sequentially a second metal layer and a photoresist layer above the first transparent conductive layer and the semiconductor layer, and using a half tone mask as a shield, the photoresist layer being subjected to photolithography from the side of the half tone mask away from the substrate, the photoresist layer being patterned to form a first photoresist pattern layer, the first photoresist pattern layer comprising a completely photolithographed non-photoresist pattern area, a partially photolithographed semi-photoresist pattern layer, and an un-photolithographed full photoresist pattern layer;
using the first photoresist pattern layer as a shield, the second metal layer being etched for the first time and the first transparent conductive layer being etched for the second time, the first transparent conductive layer being patterned to form a first electrode and a first conductive portion, wherein the first conductive portion is electrically connected to the active layer;
using a photoresist ashing process to remove the semi-photoresist pattern layer such that the first photoresist pattern layer is formed into a second photoresist pattern layer, and using the second photoresist pattern layer as a shield, the second metal layer being etched for the second time, the second metal layer forming a data line, a source, and a second conductive portion, while the first electrode and the active layer in the channel region are exposed, wherein the data line is electrically connected to the source, at least one of the first conductive portion and the second conductive portion serves as a drain, the first electrode and the channel region of the active layer correspond to the semi-photoresist pattern layer, while the data line, the source and the second conductive portion correspond to the full photoresist pattern layer.

2. The manufacturing method for an array substrate as claimed in claim 1, wherein the manufacturing method further comprises:
after etching the semiconductor layer, first forming a doped semiconductor layer above the first transparent conductive layer and the semiconductor layer, then forming sequentially the second metal layer and the photoresist layer above the doped semiconductor layer;
after the second metal layer is etched for the first time, the doped semiconductor layer being etched for the first time using the first photoresist pattern layer as a shield;
after the second metal layer is etched for the second time, the doped semiconductor layer being etched for the second time using the second photoresist pattern layer as a shield, the doped semiconductor layer being patterned to form a doped semiconductor pattern layer, wherein the doped semiconductor pattern layer is disconnected in the channel region.

3. The manufacturing method for an array substrate as claimed in claim 1, wherein the manufacturing method further comprises:
after forming the semiconductor layer, first forming a doped semiconductor layer above the semiconductor layer, then forming the positive photoresist layer above the doped semiconductor layer;
before the semiconductor layer is etched, the doped semiconductor layer being etched for the first time using the positive photoresist pattern layer as a shield;
after the second metal layer is etched for the second time, the doped semiconductor layer being etched for the second time using the second photoresist pattern layer as a shield, the doped semiconductor layer forming a doped semiconductor pattern layer, wherein the doped semiconductor pattern layer is disconnected in the channel region, and the first conductive portion and the second conductive portion are electrically connected.

4. The manufacturing method for an array substrate as claimed in claim 1, wherein the first electrode is a pixel electrode, and the first electrode is electrically connected to the first conductive portion.

5. The manufacturing method for an array substrate as claimed in claim 4, wherein the manufacturing method further comprises:
forming a second insulating layer above the first insulating layer, the second insulating layer being etched such that the second insulating layer forms a contact hole in the areas corresponding to the first electrode and the second conductive portion;
forming a second transparent conductive layer above the second insulating layer, the second transparent conductive layer being etched such that the second transparent conductive layer is patterned to form a second electrode and a third conductive portion, wherein the second electrode is a common electrode, both the third conductive portion and the first electrode are insulated from the second electrode, and the third conductive portion electrically connects the first electrode and the second conductive portion through the contact hole.

6. The manufacturing method for an array substrate as claimed in claim 1, wherein the first electrode is a common electrode, the first electrode and the first conductive portion are insulated from each other, and the manufacturing method further comprises:
forming a second insulating layer above the first insulating layer, the second insulating layer being etched to form a contact hole in the area corresponding to the second conductive portion;
forming a second transparent conductive layer above the second insulating layer, the second transparent conductive layer being etched such that the second transparent conductive layer is patterned to form a second electrode and a third conductive portion, wherein the second electrode is a pixel electrode, the third conductive portion is electrically connected to the second electrode, the second electrode and the first electrode are insulated from each other, and the third conductive portion is electrically connected to the second conductive portion through the contact hole.

7. The manufacturing method for an array substrate as claimed in claim 1, wherein the first transparent conductive layer is made of metal oxide semiconductor, and the manufacturing method further comprises:
before forming the second metal layer, the first transparent conductive layer being first subjected to conductive treatment;
after the second metal layer is etched for the second time, the active layer exposed in the channel region being subjected to hydrogen channel treatment using a hydrogen doping process.

8. The manufacturing method for an array substrate as claimed in claim 1, wherein the first transparent conductive layer is made of metal oxide semiconductor, and the manufacturing method further comprises:
after the second metal layer is etched for the second time, the first transparent conductive layer being subjected to conductive treatment.

9. The manufacturing method for an array substrate as claimed in claim 8, wherein the manufacturing method further comprises:
the first transparent conductive layer being subjected to conductive treatment using a hydrogen doping process, and the active layer exposed in the channel region also being subjected to hydrogen channel treatment simultaneously.

10. An array substrate manufactured by the manufacturing method as claimed in claim 1, the array substrate comprising:
a substrate;
a first metal layer provided above the substrate, wherein the first metal layer comprises a scanning line and a gate, the gate is electrically connected to the scanning line;
a first insulating layer provided above the first metal layer, the first insulating layer covering the scanning line and the gate;
a first transparent conductive layer and a semiconductor layer provided above the first insulating layer, wherein the first transparent conductive layer comprises a first electrode and a first conductive portion, the semiconductor layer comprises an active layer, and the first conductive portion is electrically connected to the active layer;
a second metal layer provided above the first transparent conductive layer and the semiconductor layer, wherein the second metal layer comprises a data line, a source and a second conductive portion, the data line is electrically connected to the source, and at least one of the first conductive portion and the second conductive portion serves as a drain.

11. The array substrate as claimed in claim 10, wherein the array substrate further comprises a doped semiconductor layer arranged between the semiconductor layer and the second metal layer, the doped semiconductor layer comprises a doped semiconductor pattern layer formed by patterning, and the doped semiconductor pattern layer is disconnected in the channel region of the active layer.

12. The array substrate as claimed in claim 10, wherein the first electrode is a pixel electrode, and the first electrode is electrically connected to the first conductive portion.

13. The array substrate as claimed in claim 12, wherein the array substrate further comprises:
a second insulating layer provided above the first insulating layer, wherein the second insulating layer is provided with a contact hole in the areas corresponding to the first electrode and the second conductive portion;
a second transparent conductive layer provided above the second insulating layer, wherein the second transparent conductive layer comprises a second electrode and a third conductive portion, the second electrode is a common electrode, the third conductive portion and the first electrode are both insulated from the second electrode, and the third conductive portion electrically connects the first electrode and the second conductive portion through the contact hole.

14. The array substrate as claimed in claim 12, wherein the second conductive portion and the first conductive portion are electrically connected.

15. The array substrate as claimed in claim 10, wherein the first electrode is a common electrode, the first electrode and the first conductive portion are insulated from each other, and the array substrate further comprises:
a second insulating layer provided above the first insulating layer, wherein the second insulating layer is provided with a contact hole in the area corresponding to the second conductive portion;
a second transparent conductive layer provided above the second insulating layer, wherein the second transparent conductive layer comprises a second electrode and a third conductive portion, the second electrode is a pixel electrode, the third conductive portion is electrically connected to the second electrode, the first electrode and the second electrode are insulated from each other, and the third conductive portion is electrically connected to the second conductive portion through the contact hole.
